(19) United States
(12) Patent Application Publication
(10) Pub. No.: US 2024/0297071 A1
(43) Pub. Date: Sep. 5, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Shota IZUMI, Kyoto (JP)

(73) Assignee: ROHM CO., LTD., Kyoto (JP)

(21) Appl. No.: 18/592,420

(22) Filed: Feb. 29, 2024

(30) Foreign Application Priority Data
Mar. 2, 2023 (JP) 2023-031760

(51) Int. Cl. H01L 21/763; H01L 21/762; H01L 27/088

(52) U.S. Cl. CPC H01L 21/763; H01L 21/76224; H01L 27/088

(57) ABSTRACT

A semiconductor device includes: a semiconductor chip including a first main surface and a second main surface opposite to the first main surface; and an element isolation portion formed at the first main surface and partitioning a device region. The element isolation portion includes: a first isolation trench formed at the first main surface of the semiconductor chip; an isolation insulating film formed at an inner wall of the first isolation trench; and an isolation conductor buried in the first isolation trench via the isolation insulating film. The isolation conductor includes: a main isolation conductor formed at a central portion of the first isolation trench; and at least one auxiliary isolation conductor formed at a side of the main isolation conductor with an inner insulating film, which is a portion of the isolation insulating film, interposed between the main isolation conductor and the at least one auxiliary isolation conductor.

### CROSS-REFERENCE TO RELATED APPLICATION

This application is based upon and claims the benefit of priority from Japanese Patent Application No. 2023-031760, filed on Mar. 2, 2023, the entire contents of which are incorporated herein by reference.

### TECHNICAL FIELD

The present disclosure relates to a semiconductor device and a method of manufacturing the semiconductor device.

### BACKGROUND

In the related art, a semiconductor device which includes an element isolation portion including a DTI (Deep Trench Isolation) structure is disclosed. The element isolation portion includes a trench formed at a main surface of a semiconductor chip, an insulating film covering a side surface of the trench, and polysilicon buried in the trench with the insulating film interposed therebetween. The polysilicon is electrically connected to a high-concentration impurity region via a bottom wall of the trench.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is an enlarged view of region II shown in FIG. 1.

FIG. 3 is a view showing a cross-section taken along line III-III shown in FIG. 2.

FIG. 4 is an enlarged cross-sectional view of a main part of a structure shown in FIG. 3.

FIG. 5A is a view corresponding to FIG. 4, and shows a part of a process of manufacturing the semiconductor device according to the first embodiment of the present disclosure.

FIG. 5B is a view showing a next step of FIG. 5A.

FIG. 5C is a view showing a next step of FIG. 5B.

FIG. 5D is a view showing a next step of FIG. 5C.

FIG. 5E is a view showing a next step of FIG. 5D.

FIG. 5F is a view showing a next step of FIG. 5E.

FIG. 5G is a view showing a next step of FIG. 5F.

FIG. 5H is a view showing a next step of FIG. 5G.

FIG. 5I is a view showing a next step of FIG. 5H.

FIG. 5J is a view showing a next step of FIG. 5I.

FIG. 5K is a view showing a next step of FIG. 5J.

FIG. 5L is a view showing a next step of FIG. 5K.

FIG. 6 is an enlarged cross-sectional view of a main part of a semiconductor device according to a second embodiment of the present disclosure.

FIG. 7A, which is a view corresponding to FIG. 6, shows a part of a process of manufacturing the semiconductor device according to the second embodiment of the present disclosure.

FIG. 7B is a view showing a next step of FIG. 7A.

FIG. 7C is a view showing a next step of FIG. 7B.

FIG. 7D is a view showing a next step of FIG. 7C.

FIG. 7E is a view showing a next step of FIG. 7D.

FIG. 8 is a view for illustrating a modification of an isolation trench shown in FIG. 4.

FIG. 9 is a view for illustrating a modification of an isolation insulating film shown in FIG. 4.

FIG. 10 is a view for illustrating a modification of the isolation insulating film shown in FIG. 4.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

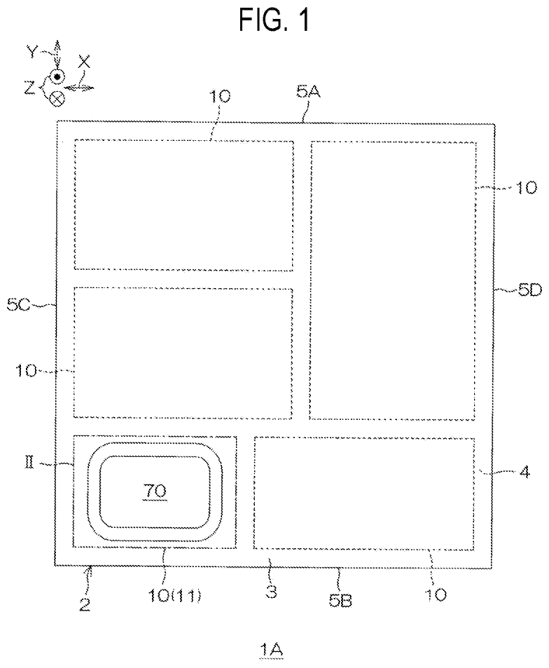

FIG. 1 is a schematic plan view of a semiconductor device 1A according to a first embodiment of the present disclosure.

Referring to FIG. 1, the semiconductor device 1A includes a semiconductor chip 2 having a rectangular parallelepiped shape. In this embodiment, the semiconductor chip 2 includes a Si (silicon) chip. The semiconductor chip 2 has a first main surface 3 on one side, a second main surface 4 on the other side, and first to fourth side surfaces 5A to 5D connecting the first main surface 3 and the second main surface 4.

The first main surface 3 and the second main surface 4 are formed in a quadrangular shape in a plan view when viewed from a normal direction Z thereof (hereinafter simply referred to as “a plan view”). The normal direction Z is also a thickness direction of the semiconductor chip 2. The first side surface 5A and the second side surface 5B extend in a first direction X along the first main surface 3 and face each other in a second direction Y that intersects (specifically, is perpendicular to) the first direction X. The third side surface 5C and the fourth side surface 5D extend in the second direction Y and face each other in the first direction X.

The semiconductor device 1A includes a plurality of device regions 10 formed at the first main surface 3. The plurality of device regions 10 are regions in which various functional devices are respectively formed using inner regions of the semiconductor chip 2. The plurality of device regions 10 are spaced apart from the first to fourth side surfaces 5A to 5D in a plan view and are each compartmentalized at an inner portion of the first main surface 3. The number, arrangement, and shape of the device regions 10 are all arbitrary, and are not limited to a specific number, arrangement, and shape.

The plurality of functional devices may each include at least one selected from the group of a semiconductor switching device, a semiconductor rectifying device, and a passive device. The semiconductor switching device may include at least one selected from the group of JFET (Junction Field Effect Transistor), MISFET (Metal Insulator Semiconductor Field Effect Transistor), BJT (Bipolar Junction Transistor), and IGBT (Insulated Gate Bipolar Junction Transistor).

The semiconductor rectifying device may include at least one selected from the group of a pn junction diode, a pin junction diode, a Zener diode, a Schottky barrier diode, and a fast recovery diode. The passive device may include at least one selected from the group of a resistor, a capacitor, an inductor, and a fuse. In this embodiment, the plurality of device regions 10 include at least one transistor region 11.

The transistor region 11 is a region where a plurality of transistor elements are formed. A current flows in the transistor region 11 in a lateral direction of the semiconductor chip 2 when source-drain of the semiconductor device 1A is in a conductive state (on state). The transistor region 11 has, for example, a quadrangular shape in a plan view.

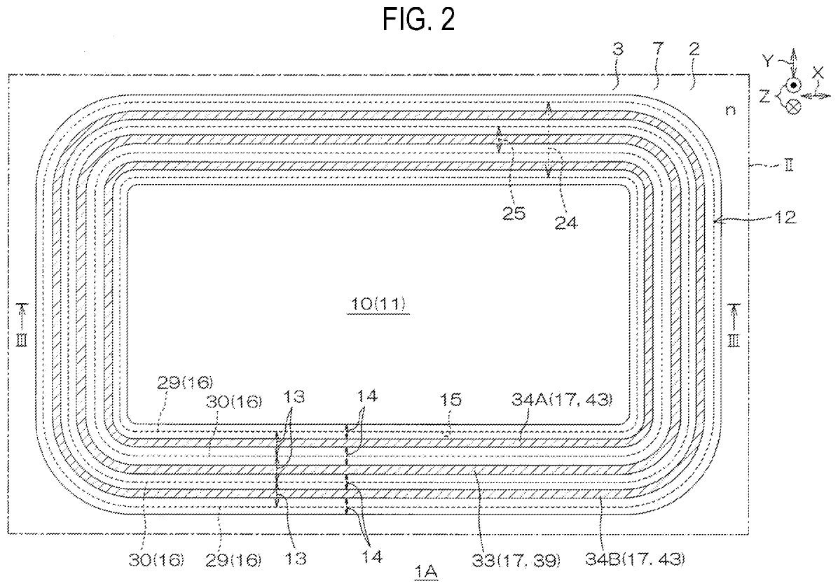

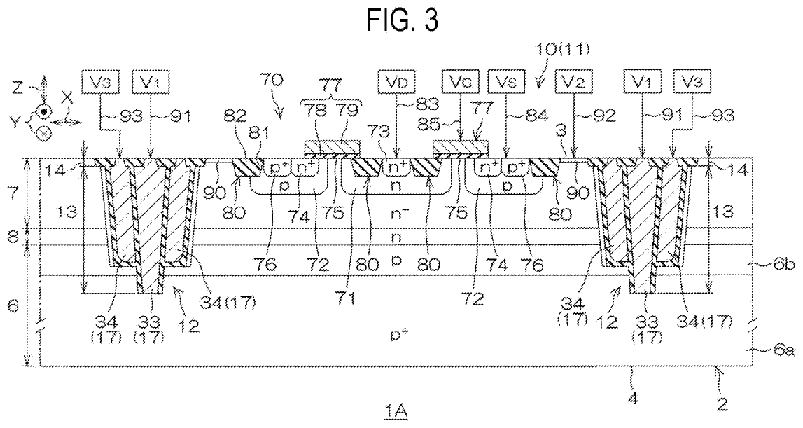

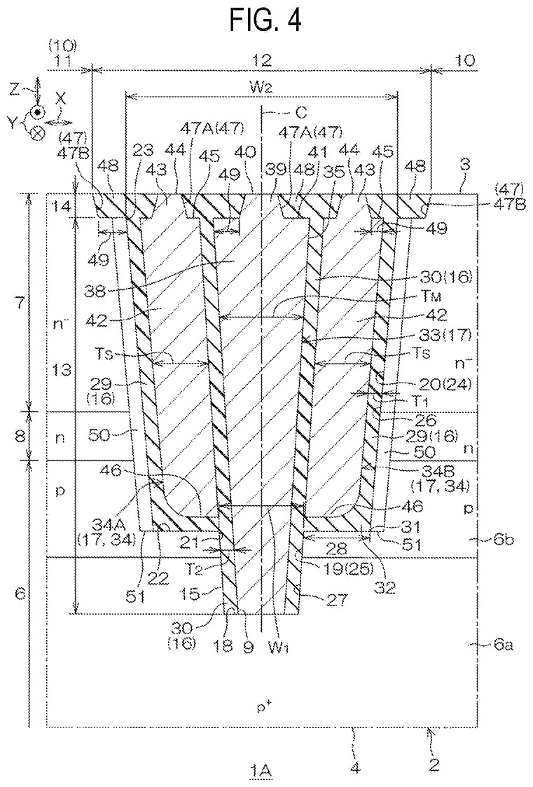

FIG. 2 is an enlarged view of region II shown in FIG. 1. FIG. 3 is a view showing a cross-section taken along line III-III shown in FIG. 2. FIG. 4 is an enlarged cross-sectional view of a main part of a structure shown in FIG. 3.

Referring to FIGS. 3 and 4, the semiconductor chip 2 includes a p-type (first conductivity type) first impurity region 6 formed at a region near the second main surface 4. The first impurity region 6 may also be referred to as a “base region.” The first impurity region 6 extends in a layered form along the second main surface 4 and is exposed from portions of the second main surface 4 and the first to fourth side surfaces 5A to 5D. The first impurity region 6 has a concentration gradient in which a p-type impurity concentration near the first main surface 3 is lower than a p-type impurity concentration near the second main surface 4. Specifically, the first impurity region 6 has a laminated structure including a p-type high-concentration region 6a and a p-type low-concentration region 6b stacked in this order from the second main surface 4. Although an outline of the second main surface 4 is not shown in the enlarged view of FIG. 4, for the sake of convenience of explanation, a place of the semiconductor chip 2 closest to the second main surface 4 is shown as the second main surface 4.

The high-concentration region 6a has a relatively high p-type impurity concentration. A p-type impurity concentration of the high-concentration region 6a may be 1×10¹⁷ cm⁻³ or more and 1×10²⁰ cm⁻³ or less. The high-concentration region 6a may include boron (B) as the p-type impurity. The high-concentration region 6a may have a thickness of 50 μm or more and 500 μm or less. In this embodiment, the high-concentration region 6a includes a p-type semiconductor substrate (Si substrate).

The low-concentration region 6b has a lower p-type impurity concentration than the high-concentration region 6a and is laminated on the high-concentration region 6a. A p-type impurity concentration of the low-concentration region 6b may be 1×10¹⁴ cm⁻³ or more and 1×10¹⁷ cm⁻³ or less. The low-concentration region 6b may contain boron (B) as the p-type impurity. The low-concentration region 6b has a thickness thinner than the thickness of the high-concentration region 6a. The thickness of the low-concentration region 6b may be 1 μm or more and 20 μm or less. In this embodiment, the low-concentration region 6b includes a p-type epitaxial layer (Si epitaxial layer).

Referring to FIG. 3, the semiconductor chip 2 includes an n-type (second conductivity type) second impurity region 7 formed in a region near the first main surface 3. The second impurity region 7 extends in a layered form along the first main surface 3 and is exposed from portions of the first main surface 3 and the first to fourth side surfaces 5A to 5D. An n-type impurity concentration of the second impurity region 7 may be 1×10¹⁴ cm⁻³ or more and 1×10¹⁷ cm⁻³ or less. The second impurity region 7 may have a thickness of 5 μm or more and 30 μm or less. The second impurity region 7 may have a uniform n-type impurity concentration in a thickness direction, or may have a concentration gradient in which the n-type impurity concentration increases toward the first main surface 3. The second impurity region 7 may include an n-type epitaxial layer (Si epitaxial layer).

The semiconductor chip 2 includes an n-type (second conductivity type) buried region 8 buried between the first impurity region 6 and the second impurity region 7. In other words, the first impurity region 6, the buried region 8, and the second impurity region 7 are laminated in this order from the second main surface 4. The buried region 8 is electrically connected to the first impurity region 6 and the second impurity region 7. The buried region 8 extends in a layered form along the second impurity region 7. The buried region 8 is exposed from portions of the first to fourth side surfaces 5A to 5D. The n-type impurity concentration of the buried region 8 is higher than the n-type impurity concentration of the second impurity region 7 and may be, for example, 1×10¹⁶ cm⁻³ or more and 1×10²¹ cm⁻³ or less. The buried region 8 may have a thickness of 0.1 μm or more and 5 μm or less. The buried region 8 may include an n-type epitaxial layer (Si epitaxial layer).

Referring to FIGS. 2 and 3, the semiconductor chip 2 includes an element isolation portion 12 formed near the first main surface 3 and partitioning the transistor region 11. The element isolation portion 12 has an annular shape, specifically a quadrangular annular shape, in a plan view. More specifically, the element isolation portion 12 has a quadrangular annular shape having corner portions (four corners) curved in an arc-shape in a plan view.

The element isolation portion 12 includes a first trench structure 13 and a second trench structure 14 formed near the first main surface 3 with respect to the first trench structure 13.

Referring to FIG. 2, the first trench structure 13 and the second trench structure 14 overlap each other in a plan view. The second trench structure 14 is formed at an upper portion of the first trench structure 13. Both the first trench structure 13 and the second trench structure 14 have an annular shape, specifically a quadrangular annular shape, in a plan view.

The first trench structure 13 includes an isolation trench 15, an isolation insulating film 16, and an isolation conductor 17.

Referring to FIG. 2, the isolation trench 15 (an example of a first isolation trench) is formed near the first main surface 3 so as to partition the transistor region 11. In this embodiment, the isolation trench 15 has an annular shape (in this embodiment, a quadrangular annular shape) in a plan view. More specifically, the isolation trench 15 has corner portions (four corners) curved in an arc shape in a plan view.

Referring to FIG. 4, the isolation trench 15 penetrates the second impurity region 7 and the buried region 8 to reach the first impurity region 6. A bottom 18 of the isolation trench 15 is located in the first impurity region 6. The bottom 18 of the isolation trench 15 may also be referred to as a bottom wall of the isolation trench 15. Specifically, the isolation trench 15 extends from the first main surface 3 toward the second main surface 4 so as to reach the high-concentration region 6a of the first impurity region 6, and penetrates the second impurity region 7, the buried region 8, and the low-concentration region 6b of the first impurity region 6.

The isolation trench 15 has a step structure consisting of a plurality of portions having different widths. In this embodiment, the isolation trench 15 includes a first portion 19 formed near the bottom 18 of the isolation trench 15 and a second portion 20 formed near the first main surface 3 with respect to the first portion 19. The first portion 19 and the second portion 20 of the isolation trench 15 may also be referred to as a lower portion and an upper portion of the isolation trench 15, respectively. Further, based on a width relationship to be described later, the first portion 19 may also be referred to as a narrow portion of the isolation trench 15, and the second portion 20 may also be referred to as a wide portion of the isolation trench 15.

In this embodiment, the entire first portion 19 of the isolation trench 15 from the bottom 18 to a top 21 is formed within the first impurity region 6. The top 21 may also be a boundary with the second portion 20 of the isolation trench 15. The first portion 19 of the isolation trench 15 crosses a boundary between the high-concentration region 6a and the low-concentration region 6b in the thickness direction of the semiconductor chip 2 and may include the bottom 18 in the high-concentration region 6a and the top 21 in the low-concentration region 6b.

The first portion 19 of the isolation trench 15 is formed in a tapered shape whose width increases from the bottom 18 toward the top 21 in a cross-sectional view. The first portion 19 of the isolation trench 15 has a first width W₁ at the top 21. The first width W₁ is a width in a direction perpendicular to a direction in which the isolation trench 15 extends in a plan view. The first width W₁ may be 0.5 μm or more and 5.0 μm or less.

In this embodiment, the second portion 20 of the isolation trench 15 crosses a boundary between the first impurity region 6 and the buried region 8 and a boundary between the buried region 8 and the second impurity region 7 in the thickness direction of the semiconductor chip 2. The second portion 20 of the isolation trench 15 may have a bottom 22 in the first impurity region 6 (in this embodiment, the low-concentration region 6b) and a top 23 in the second impurity region 7. The bottom 22 is integrally connected to the top 21 of the first portion 19 of the isolation trench 15. The bottom 22 may also be referred to as a bottom wall of the second portion 20 of the isolation trench 15.

The second portion 20 of the isolation trench 15 is formed to extend from the first portion 19 toward an outside of the isolation trench 15. That is, the second portion 20 of the isolation trench 15 extends out from the first portion 19 toward both the transistor region 11 and an opposite side thereof.

The second portion 20 of the isolation trench 15 is formed in a tapered shape whose width increases from the bottom 22 toward the top 23 in a cross-sectional view. The second portion 20 of the isolation trench 15 has a second width W₂ at the top 23, which is wider than the first width W₁. The second width W₂ is a width in a direction perpendicular to the direction in which the isolation trench 15 extends in a plan view. The second width W₂ may be, for example, 1.0 μm or more and 10.0 μm or less.

The isolation trench 15 may include an upper trench 24 corresponding to the second portion 20, and a lower trench 25 corresponding to the first portion 19 and formed with a narrower width than the upper trench 24. In this embodiment, the isolation trench 15 has a two-stage trench structure including the upper trench 24 formed from the first main surface 3 toward the second main surface 4 and the lower trench 25 formed by selectively digging a portion of the semiconductor chip 2 from the bottom 22 of the upper trench 24.

Therefore, a step portion 28 in the direction along the first main surface 3 is formed between a side wall 26 of the upper trench 24 (the second portion 20) and a side wall 27 of the lower trench 25 (the first portion 19). A width of the step portion 28 corresponds to a width of the bottom 22 of the upper trench 24. In a plan view, as shown in FIG. 2, the isolation trench 15 has a double annular structure including the relatively wide upper trench 24 and the relatively narrow lower trench 25.

The isolation insulating film 16 is formed in an inner wall of the isolation trench 15. A contact opening 9 is formed at a portion on the bottom 18 of the isolation insulating film 16. The contact opening 9 exposes the first impurity region 6 within the isolation trench 15.

In this embodiment, the isolation insulating film 16 is SiO₂ (silicon oxide). The isolation insulating film 16 includes an outer insulating film 29 and an inner insulating film 30.

The outer insulating film 29 is a film that insulates the semiconductor chip 2 and the isolation conductor 17 from each other and is formed at the inner wall of the upper trench 24 (the second portion 20). The outer insulating film 29 is formed along the side wall 26 and bottom 22 of the upper trench 24. The outer insulating film 29 has a uniform first thickness T₁ on the side wall 26 and the bottom 22.

The first thickness T₁ may be an appropriate size depending on a third potential V₃ (see FIG. 3) of an auxiliary isolation conductor 34 of the isolation conductor 17, which will be described later. The first thickness T₁ may be, for example, 100 Å or more and 500 Å or less. However, the outer insulating film 29 may selectively have a thick film portion 32 at a corner 31 where the side wall 26 and the bottom 22 intersect each other. As a result, a breakdown voltage of the isolation insulating film 16 at the corner 31 of the upper trench 24 may be improved.

The isolation conductor 17 is buried at an inner side of the outer insulating film 29 in the isolation trench 15. The isolation conductor 17 is polysilicon. In this embodiment, this polysilicon is doped polysilicon added with p-type (first conductivity type) impurities (for example, boron (B)). The isolation conductor 17 may be electrically connected to the first impurity region 6 exposed from the contact opening 9.

The isolation conductor 17 includes a main isolation conductor 33 and the auxiliary isolation conductor 34 that are insulated and separated by the inner insulating film 30. The main isolation conductor 33 and the auxiliary isolation conductor 34 may also be referred to as a first isolation conductor and a second isolation conductor, respectively. The main isolation conductor 33 is formed at a central portion of the isolation trench 15, and the auxiliary isolation conductors 34 are formed on both sides of the main isolation conductor 33 with the inner insulating film 30 interposed therebetween. The main isolation conductor 33 is formed to be deeper than the auxiliary isolation conductor 34 and is electrically connected to the first impurity region 6 exposed from the contact opening 9. On the other hand, the auxiliary isolation conductor 34 is covered with the outer insulating film 29 and the inner insulating film 30 and is insulated from a laminated structure of the first impurity region 6, the buried region 8, and the second impurity region 7.

In this embodiment, the main isolation conductor 33 is buried in the lower trench 25 (the first portion 19) of the isolation trench 15 and is formed in a shape of a wall extending upward from the lower trench 25 toward the first main surface 3. Referring to FIG. 2, in this embodiment, the main isolation conductor 33 has an annular shape (in this embodiment, a quadrangular annular shape) in a plan view. More specifically, the main isolation conductor 33 has corner portions (four corners) curved in an arc shape in a plan view.

Referring to FIG. 4, the main isolation conductor 33 is formed along the side wall 27 of the lower trench 25 and has a flat side wall 35 extending parallel to an extension line of the side wall 27 in a cross-sectional view in the upper trench 24 above the lower trench 25. As a result, the main isolation conductor 33 is formed in a tapered shape whose width increases from the bottom 18 toward the top 23 in a cross-sectional view. A thickness T_{M} of the main isolation conductor 33 in the lateral direction along the first main surface 3 may be, for example, 0.3 μm or more and 4.8 μm or less.

The main isolation conductor 33 integrally includes a main body portion 38 and a protrusion portion 39. The main body portion 38 is a portion sandwiched between the inner insulating films 30 in a cross-sectional view. The protrusion portion 39 extends from an upper end of the main body portion 38 toward the first main surface 3 and is exposed from the first main surface 3. Referring to FIG. 2, an exposed surface of the protrusion portion 39 has a quadrangular annular shape in a plan view.

The main isolation conductor 33 may have a first upper surface 40, which is an upper surface of the protrusion portion 39, and a second upper surface 41 formed at a lower level than the first upper surface 40. The protrusion portion 39 may be formed by selectively having a portion of a top of the main isolation conductor 33 protrude. The second upper surface 41 is formed on one side and the other side of the protrusion portion 39 with the protrusion portion 39 sandwiched therebetween.

The auxiliary isolation conductor 34 is formed in a shape of a wall buried from the bottom 22 of the upper trench 24 to a surface layer of the first main surface 3 in a space between the main isolation conductor 33 and the side wall 26 of the upper trench 24. Referring to FIG. 2, in this embodiment, the auxiliary isolation conductor 34 has an annular shape (in this embodiment, a quadrangular annular shape) in a plan view. More specifically, the auxiliary isolation conductor 34 has corner portions (four corners) curved in an arc-shape in a plan view.

As a result, the auxiliary isolation conductor 34 is sandwiched between the main isolation conductor 33 and both the second impurity region 7 and the buried region 8 in the lateral direction along the first main surface 3. The buried region 8 is covered with the auxiliary isolation conductor 34 with the outer insulating film 29 interposed therebetween, at an intermediate portion in a depth direction of the isolation trench 15.

In this embodiment, the auxiliary isolation conductor 34 includes a pair of auxiliary isolation conductors 34 that are separated from each other in a cross-sectional view. The pair of auxiliary isolation conductors 34 may include an inner auxiliary isolation conductor 34A that has an annular shape in a plan view surrounded by the main isolation conductors 33 and is relatively disposed closer to the transistor region 11, and an outer auxiliary isolation conductor 34B that has an annular shape in a plan view surrounding the main isolation conductor 33 and is disposed opposite to the inner auxiliary isolation conductor 34A.

In this way, the pair of auxiliary isolation conductors 34 extend out from the main isolation conductor 33 toward both the transistor region 11 and the opposite side thereof, and are supported from below by the step portion 28 of the isolation trench 15. Lower ends 46 of the pair of auxiliary isolation conductors 34 are arranged in the low-concentration region 6b, among the high-concentration region 6a and the low-concentration region 6b of the first impurity region 6.

The pair of auxiliary isolation conductors 34 face each other with the main isolation conductor 33 interposed therebetween. The pair of auxiliary isolation conductors 34 are formed in line symmetry to a center line C extending from a center at a width direction of the bottom 18 of the isolation trench 15, so as to have a same thickness T_{S}. The thickness T_{S} of the auxiliary isolation conductor 34 in the lateral direction along the first main surface 3 may be, for example, 0.3 μm or more and 4.8 μm or less. The thickness T_{S} of the auxiliary isolation conductor 34 may be thinner or thicker than the thickness T_{M} of the main isolation conductor 33.

The auxiliary isolation conductor 34 integrally includes a main body portion 42 and a protrusion portion 43. The main body portion 42 is a portion sandwiched between the outer insulating film 29 and the inner insulating film 30 in a cross-sectional view. The protrusion portion 43 extends from an upper end of the main body portion 42 toward the first main surface 3 and is exposed from the first main surface 3. Referring to FIG. 2, an exposed surface of the protrusion portion 43 has a quadrangular annular shape in a plan view.

The auxiliary isolation conductor 34 may have a first upper surface 44, which is an upper surface of the protrusion portion 43, and a second upper surface 45 formed at a lower level than the first upper surface 44. The protrusion portion 43 may be formed by selectively having a portion of a top of the auxiliary isolation conductor 34 protrude. The second upper surface 45 is formed on one side and the other side of the protrusion portion 43 with the protrusion portion 43 sandwiched therebetween.

The inner insulating film 30 is a film that insulates the main isolation conductor 33 and the auxiliary isolation conductor 34 from each other and is formed between the main isolation conductor 33 and the auxiliary isolation conductor 34 and at an inner wall of the lower trench 25 (the first portion 19). The inner insulating film 30 covers the side wall 35 of the main isolation conductor 33 with a uniform second thickness T₂.

The second thickness T₂ may be an appropriate size depending on a first potential V₁ (see FIG. 3) of the main isolation conductor 33 and the third potential V₃ (see FIG. 3) of the auxiliary isolation conductor 34, which will be described later. The second thickness T₂ may be the same as or different from the first thickness T₁. The second thickness T₂ may be, for example, 100 Å or more and 500 Å or less.

The contact opening 9 is formed at a portion on the bottom 18 of the inner insulating film 30. The contact opening 9 exposes the first impurity region 6 within the isolation trench 15.

A plurality of second trench structures 14 are formed. The plurality of second trench structures 14 may also be referred to as STI (Shallow Trench Isolation) structures. The plurality of second trench structures 14 cover the outer insulating film 29 and the inner insulating film 30 and are spaced apart from each other to expose the protrusion portion 39 of the main isolation conductor 33 and the protrusion portion 43 of the auxiliary isolation conductor 34.

The plurality of second trench structures 14 are formed at intervals from the buried region 8 toward the first main surface 3. That is, the plurality of second trench structures 14 are formed within a thickness range of the second impurity region 7. The second trench structure 14 extends along the first trench structure 13 in a plan view. In this embodiment, the second trench structure 14 is formed in an annular shape (in this embodiment, a quadrangular annular shape) extending along the first trench structure 13 in a plan view.

Each second trench structure 14 includes a shallow trench 47 as an example of a second isolation trench, and a buried insulator 48.

The shallow trench 47 includes a first shallow trench 47A that crosses a boundary between the main isolation conductor 33 and the auxiliary isolation conductor 34 and a second shallow trench 47B that crosses a boundary between the auxiliary isolation conductor 34 and the second impurity region 7 in the lateral direction along the first main surface 3. The shallow trench 47 includes a lead-out portion 49 led out toward both the transistor region 11 and the opposite side thereof in a thickness direction of the main isolation conductor 33 and the auxiliary isolation conductor 34.

The buried insulator 48 is buried in the shallow trench 47. The buried insulator 48 within the first shallow trench 47A is formed integrally with the inner insulating film 30. The buried insulator 48 within the second shallow trench 47B is formed integrally with the outer insulating film 29. The buried insulator 48 may include at least one selected from the group of an oxide film such as silicon oxide and a nitride film such as silicon nitride.

The semiconductor chip 2 further includes an n-type sinker region 50. The sinker region 50 has a higher n-type impurity concentration than the second impurity region 7. For example, the n-type impurity concentration of the sinker region 50 may be 1.0×10¹⁷ cm⁻³ or more and 1.0×10²² cm⁻³ or less. The sinker region 50 is formed along the side wall 26 of the isolation trench 15 in a vicinity of an interface with the auxiliary isolation conductor 34 in the second impurity region 7. The sinker region 50 is selectively formed at the side wall 26 of the isolation trench 15, among the side walls 26 and 27 of the isolation trench 15, and is not formed at the side wall 27 of the isolation trench 15. Therefore, a lower end 51 of the sinker region 50 is formed at a depth position of the step portion 28 of the isolation trench 15.

Referring to FIG. 3, the semiconductor device 1A includes a planar gate type MISFET cell 70 as an example of a functional device formed in the transistor region 11. In FIG. 2, illustration of the MISFET cell 70 is omitted. Depending on a magnitude of a drain-source voltage of the MISFET cell 70, the MISFET cell 70 may take the form of one of a HV (High Voltage)-MISFET cell (for example, 100 V or more and 1,000 V or less), a MV (Middle Voltage)-MISFET cell (for example, 30 V or more and 100 V or less), and a LV (Low Voltage)-MISFET cell (for example, 1 V or more and 30 V or less). In this embodiment, an example will be described in which the MISFET cell 70 is the HV-MISFET cell, but this is not intended to limit the form of the MISFET cell 70 to the HV-MISFET cell.

In a cross-sectional view, the MISFET cell 70 includes at least one (in this embodiment, one) n-type first well region 71, at least one (in this embodiment, a plurality of) p-type second well region 72, at least one (in this embodiment, one) n-type drain region 73, at least one (in this embodiment, a plurality of) n-type source region 74, at least one (in this embodiment, a plurality of) p-type channel region 75, at least one (in this embodiment, a plurality of) p-type contact region 76, and at least one (in this embodiment, a plurality of) planar gate structure 77.

The first well region 71 is formed at a surface layer of the second impurity region 7 in the transistor region 11. The first well region 71 has a higher n-type impurity concentration than the second impurity region 7. The plurality of second well regions 72 are formed at the surface layer of the second impurity region 7 at intervals from the first well region 71 in the transistor region 11. One second well region 72 is formed at an interval from the first well region 71 on one side in the first direction X, and the other second well region 72 is formed at an interval from the first well region 71 on the other side in the first direction X.

The drain region 73 is formed at a surface layer of the first well region 71 at an interval inward from a periphery of the first well region 71. The plurality of source regions 74 are respectively formed at surface layers of the corresponding second well regions 72 at intervals inward from peripheries of the corresponding second well regions 72. The plurality of channel regions 75 are respectively formed between the second impurity region 7 and the source regions 74 at the surface layers of the corresponding second well regions 72. The plurality of contact regions 76 are respectively formed at the surface layers of the corresponding second well regions 72 at intervals inward from the peripheries of the corresponding second well regions 72. The plurality of contact regions 76 are adjacent to the corresponding source regions 74.

The plurality of planar gate structures 77 are respectively formed over the first main surface 3 so as to cover the corresponding channel regions 75, and control on/off states of the corresponding channel regions 75. In this embodiment, the plurality of planar gate structures 77 are respectively formed so as to extend over the first well region 71 and the corresponding source regions 74.

The plurality of planar gate structures 77 include a gate insulating film 78 and a gate electrode 79 laminated in this order from the first main surface 3. The gate insulating film 78 may include silicon oxide (SiO₂) or may include a tetraethyl orthosilicate (TEOS) film. Preferably, the gate insulating film 78 includes a silicon oxide film made of oxide of the semiconductor chip 2. Preferably, the gate electrode 79 includes polysilicon. The gate electrode 79 may include one or both of an n-type region and a p-type region formed in polysilicon.

Referring to FIG. 3, the semiconductor device 1A includes a plurality of third trench structures 80 formed at the first main surface 3. The plurality of third trench structures 80 may also be referred to as STI structures. In this embodiment, the plurality of third trench structures 80 are formed at intervals from each other so as to partition the drain region 73 from other regions and to partition outer edges of the plurality of second well regions 72 from other regions.

In this embodiment, the plurality of third trench structures 80 are formed at a distance from the buried region 8 toward the first main surface 3. That is, the plurality of third trench structures 80 are formed within the thickness range of the second impurity region 7.

Each of the third trench structures 80 includes a shallow trench 81 and a buried insulator 82. The shallow trench 81 is dug down from the first main surface 3 toward the second main surface 4. The buried insulator 82 is buried in the shallow trench 81. The buried insulator 82 may include at least one selected from the group of silicon oxide and silicon nitride.

In the transistor region 11, a drain potential V_{D} is applied to the drain region 73 via a drain contact electrode 83. In FIG. 3, the drain contact electrode 83 is shown in a simplified manner by an arrow. The drain potential V_{D} is a positive device potential in the transistor region 11. A source potential V_{S} lower than the drain potential V_{D} is applied to the source region 74 via a source contact electrode 84. In FIG. 3, the source contact electrode 84 is shown in a simplified manner by an arrow. A gate potential V_{G} is applied to the gate electrode 79 via a gate contact electrode 85. In FIG. 3, the gate contact electrode 85 is shown in a simplified manner by an arrow.

The first potential V₁ is applied to the main isolation conductor 33 via a contact electrode 91. In FIG. 3, the contact electrode 91 is shown in a simplified manner by an arrow. The first potential V₁ applied to the main isolation conductor 33 is applied to the high-concentration region 6a via the main isolation conductor 33. As a result, the high-concentration region 6a is fixed at a same potential as the main isolation conductor 33. The first potential V₁ is preferably a potential equal to or lower than the drain potential V_{D} (preferably lower than the drain potential V_{D}). That is, the first potential V₁ is preferably lower than a maximum device potential. The first potential V₁ may be a reference potential serving as a reference for circuit operation or a ground potential. Preferably, the first potential V₁ is the ground potential.

A second potential V₂ is applied to a back gate contact region 90, which is formed between the first trench structure 13 and the transistor region 11 in the semiconductor chip 2, via a second contact electrode 92. In FIG. 3, the second contact electrode 92 is shown in a simplified manner by an arrow. The second potential V₂ is preferably a potential equal to or lower than the drain potential V_{D} (preferably lower than the drain potential V_{D}). Preferably, the second potential V₂ is lower than the maximum device potential. The second potential V₂ may be equal to or higher than the first potential V₁ (V₁≤V₂). The second potential V₂ may also exceed the first potential V₁ (V₁<V₂). The second potential V₂ may be a reference potential or a ground potential.

The third potential V₃ is applied to the auxiliary isolation conductor 34 via a third contact electrode 93. In FIG. 3, the third contact electrode 93 is shown in a simplified manner by an arrow. The third potential V₃ is preferably an intermediate potential between the first potential V₁ and the second potential V₂ (V₁<V₃<V₂). When the third potential V₃ is the intermediate potential between the first potential V₁ and the second potential V₂, a voltage decreases stepwise from the second potential V₂ toward the first potential V₁, and thus an electric field may be relaxed stepwise in the lateral direction along the first main surface 3.

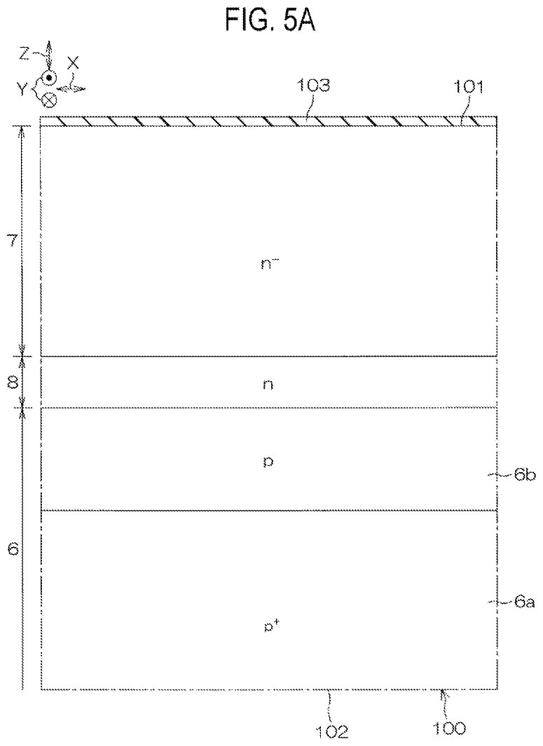

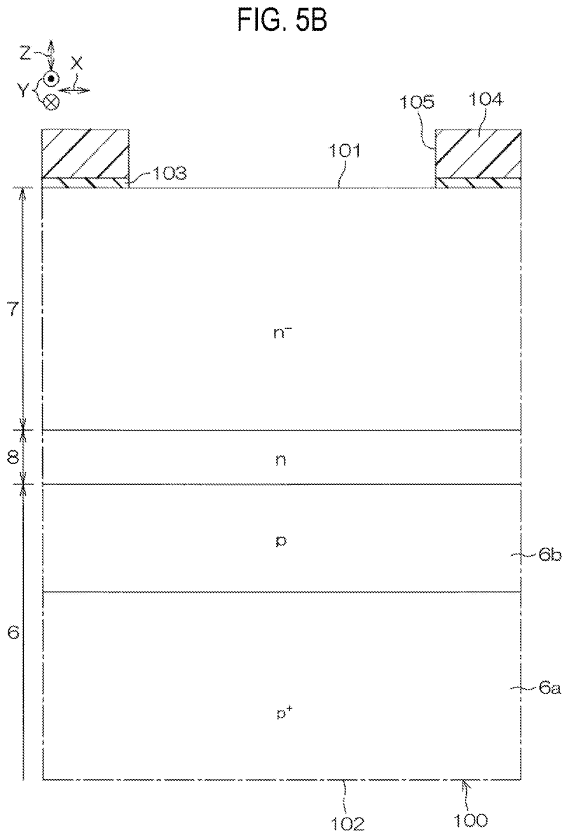

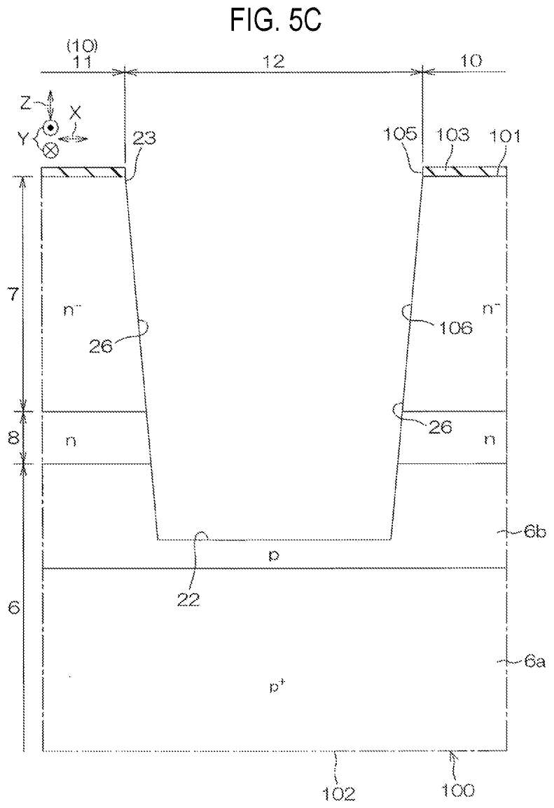

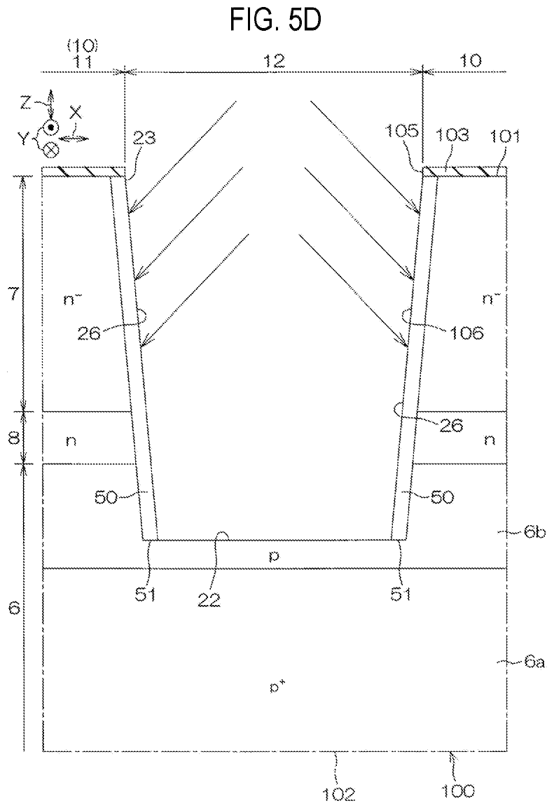

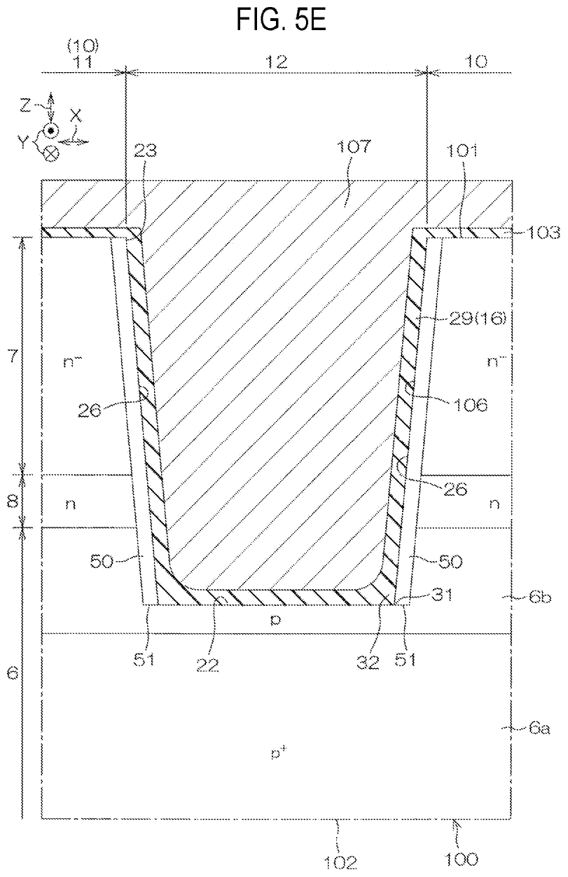

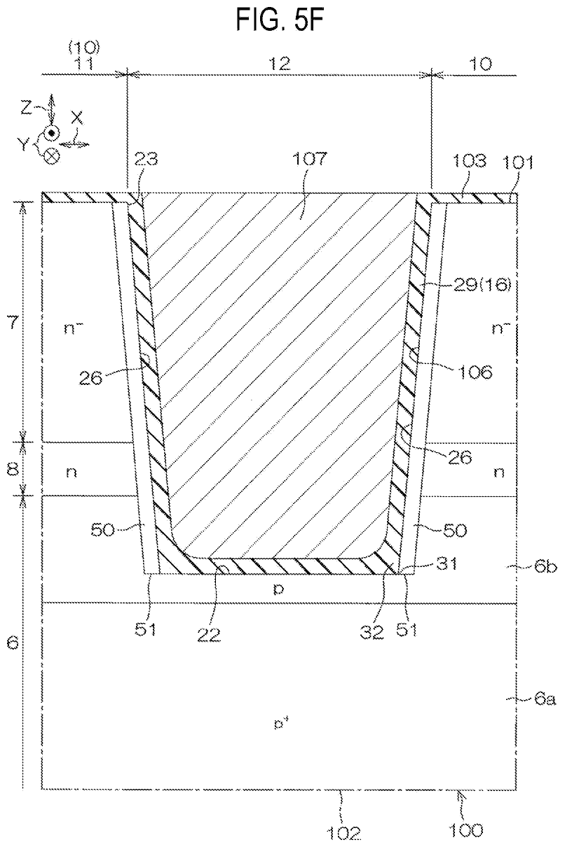

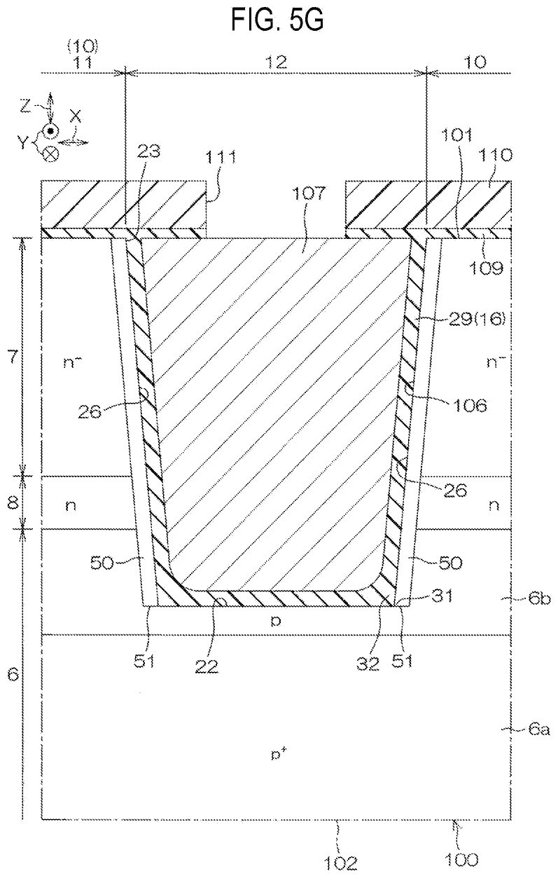

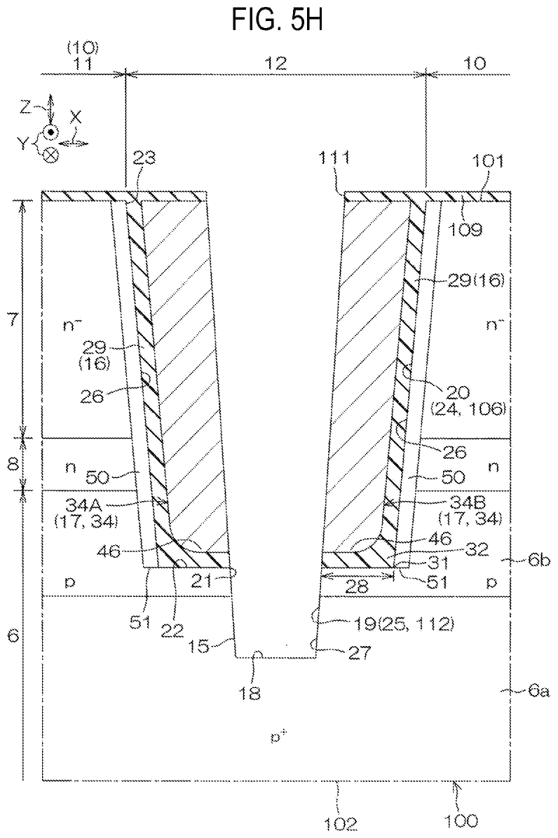

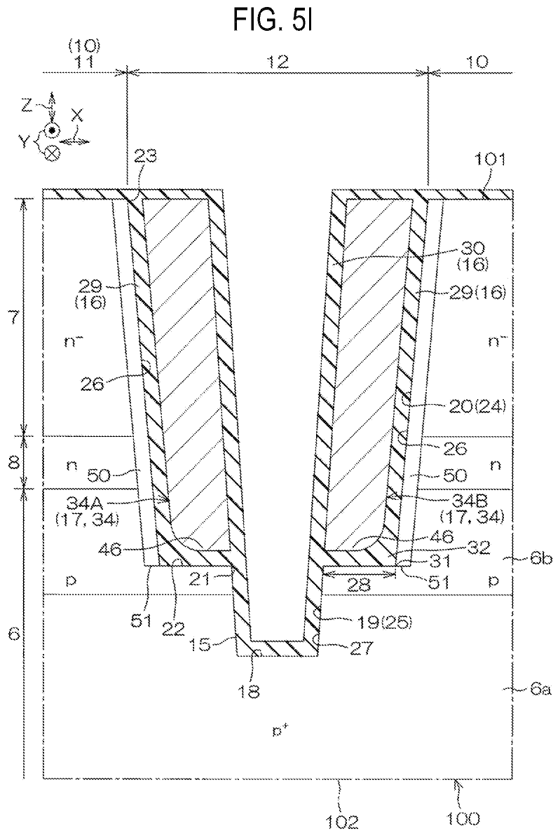

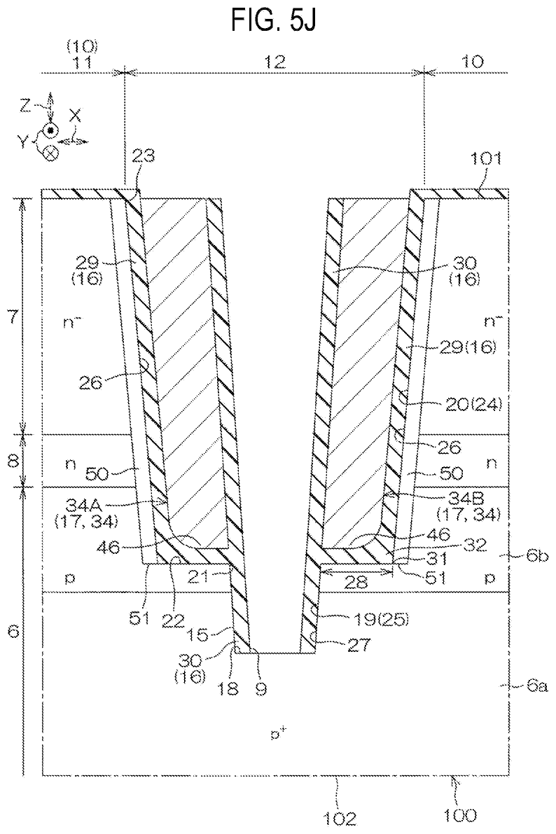

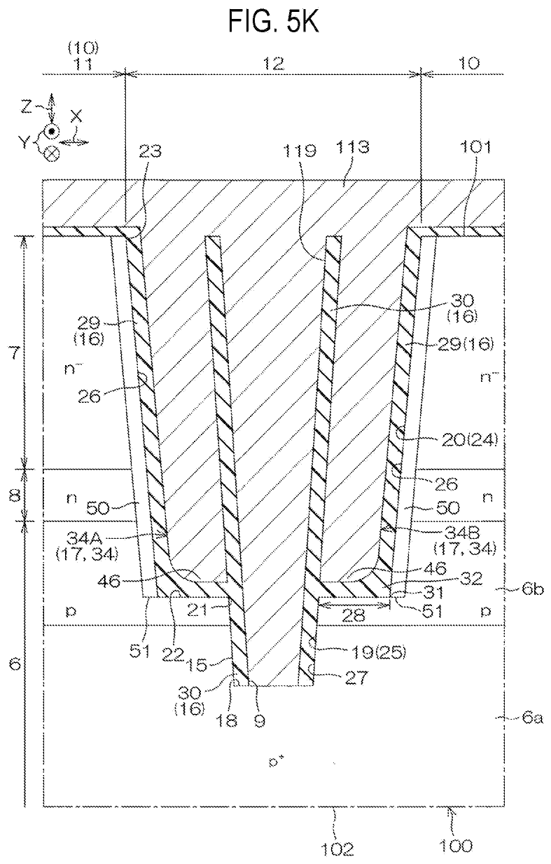

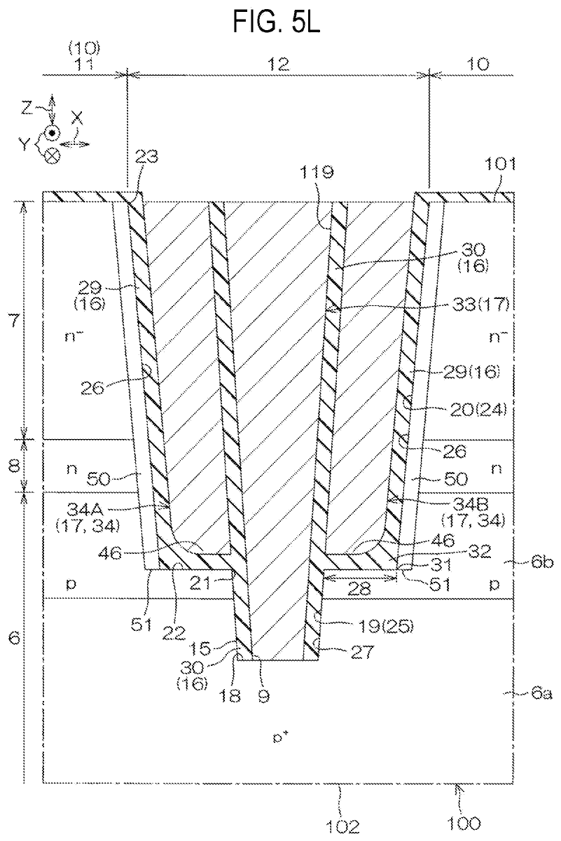

FIGS. 5A to 5L, which are views corresponding to FIG. 4, show parts of a process of manufacturing the semiconductor device 1A according to the first embodiment of the present disclosure.

Referring to FIG. 5A, in order to manufacture the semiconductor device 1A, a semiconductor wafer 100 that becomes a base of the semiconductor chip 2 is prepared. The semiconductor wafer 100 has a first wafer main surface 101 corresponding to the first main surface 3 and a second wafer main surface 102 corresponding to the second main surface 4. Although an outline of the second wafer main surface 102 is not shown in the enlarged view of FIG. 5A, for the sake of convenience of explanation, a place of the semiconductor wafer 100 closest to the second wafer main surface 102 is shown as the second wafer main surface 102.

The semiconductor wafer 100 includes the first impurity region 6, the second impurity region 7, and the buried region 8. The first impurity region 6 includes the high-concentration region 6a and the low-concentration region 6b. The high-concentration region 6a includes a p-type semiconductor substrate. The low-concentration region 6b includes a p-type epitaxial layer, which is laminated on the semiconductor substrate, by an epitaxial growth method.

Next, a mask 103 is formed over the entire first wafer main surface 101 of the semiconductor wafer 100. The mask 103 may be a hard mask made of, for example, silicon oxide (SiO₂). The mask 103 is formed by, for example, a thermal oxidation method or a CVD method.

Next, referring to FIG. 5B, a resist 104 is formed over the mask 103. The resist 104 has an opening 105 having a shape corresponding to the upper trench 24 (the second portion 20) of the isolation trench 15. By selectively etching the mask 103 through the opening 105, the opening 105 penetrates the mask 103 to reach the first wafer main surface 101.

Next, referring to FIG. 5C, the semiconductor wafer 100 is selectively etched through the opening 105 of the mask 103. As a result, an annular first trench 106 is formed at the first wafer main surface 101 to partition the transistor region 11 (the device region 10). The first trench 106 penetrates the second impurity region 7 and the buried region 8 to expose the low-concentration region 6b. The first trench 106 is formed in a tapered shape whose width increases from the bottom 22 toward the first wafer main surface 101 in a cross-sectional view. The etching method may be a dry etching method or a wet etching method.

The first trench 106 has a shape that becomes a base of the upper trench 24 (the second portion 20) of the isolation trench 15, and has the side wall 26 and the bottom 22. At this stage, the bottom 22 is not divided at a region between the side wall 26 on one side and the side wall 26 on the other side in a cross-sectional view, and connects the pair of side walls 26 at a lower end of the first trench 106.

Next, referring to FIG. 5D, an n-type impurity is implanted into an inner wall of the first trench 106. The n-type impurity is implanted obliquely at a certain angle with respect to the first wafer main surface 101. As a result, the sinker region 50 having a higher concentration than the second impurity region 7 is formed. The sinker region 50 is formed with the mask 103 remaining over the first wafer main surface 101. This may prevent an entire surface layer of the first wafer main surface 101 from being transformed into an n-type impurity region having a same concentration as the sinker region 50.

Next, referring to FIG. 5E, the outer insulating film 29 is formed at the inner wall of the first trench 106 and the first wafer main surface 101. The outer insulating film 29 is formed by, for example, a thermal oxidation method or a CVD method. Next, a polysilicon material 107, which becomes a base of the auxiliary isolation conductor 34, is deposited on the first wafer main surface 101. In this embodiment, the polysilicon material 107 includes doped polysilicon added with p-type (first conductivity type) impurities. The deposition of the polysilicon material 107 continues until the first trench 106 is filled. The polysilicon material 107 may be deposited by a CVD method.

Next, referring to FIG. 5F, unnecessary portions of the deposited polysilicon material 107 are removed. This step includes a step of removing the polysilicon material 107 by a grinding method until the outer insulating film 29 is exposed. The grinding method may be a CMP (Chemical Mechanical Polishing) method.

Next, referring to FIG. 5G, the mask 103 is removed and another mask 109 is newly formed over the entire first wafer main surface 101. The mask 109 may be a hard mask made of, for example, silicon oxide (SiO₂). The mask 109 is formed by, for example, a thermal oxidation method or a CVD method. Next, a resist 110 is formed over the mask 109. The resist 110 has an opening 111 having a shape corresponding to the lower trench 25 (the first portion 19) of the isolation trench 15. By selectively etching the mask 109 through the opening 111, the opening 111 penetrates the mask 109 to reach the polysilicon material 107.

Next, referring to FIG. 5H, the polysilicon material 107 is selectively etched through the opening 111 of the mask 109. The etching of the polysilicon material 107 continues until the outer insulating film 29 of the bottom 22 of the first trench 106 is exposed. As a result, the polysilicon material 107 is separated, and the pair of auxiliary isolation conductors 34 are formed. Next, the outer insulating film 29 exposed between the pair of auxiliary isolation conductors 34 is removed, and then the bottom 22 of the first trench 106 is further etched. As a result, a second trench 112 having a width narrower than that of the first trench 106 is formed, and the isolation trench 15 having a two-stage trench structure is formed. At this step, a portion of the first impurity region 6 is exposed at the side wall of the first portion 19 of the isolation trench 15.

Next, referring to FIG. 5I, the inner insulating film 30 is formed at an inner wall of the second trench 112. The inner insulating film 30 may be formed, for example, by thermal oxidation of the first impurity region 6 and the auxiliary isolation conductor 34 exposed as the inner wall of the second trench 112.

Next, referring to FIG. 5J, the contact opening 9 is formed by selectively etching the inner insulating film 30 on the bottom 18 of the isolation trench 15.

Next, referring to FIG. 5K, a polysilicon material 113, which becomes a base of the main isolation conductor 33, is deposited on the first wafer main surface 101. In this embodiment, the polysilicon material 113 includes doped polysilicon added with p-type (first conductivity type) impurities. The deposition of the polysilicon material 113 continues until an inner space 119 of the inner insulating film 30 of the second trench 112 is filled. The polysilicon material 113 may be deposited by a CVD method.

Next, referring to FIG. 5L, unnecessary portions of the deposited polysilicon material 113 are removed. This step includes a step of removing the polysilicon material 113 by a grinding method until the outer insulating film 29 and the inner insulating film 30 on the first wafer main surface 101 are exposed. The grinding method may be a CMP (Chemical Mechanical Polishing) method. As a result, the main isolation conductor 33 is formed by the polysilicon material 113 remaining in the second trench 112. As a result, the first trench structure 13 is formed. Of course, in this step, an etching method (wet etching method or dry etching method) may be employed instead of the grinding method. After the main isolation conductor 33 is formed, the outer insulating film 29 and the inner insulating film 30 remaining on the first wafer main surface 101 are removed.

Next, the shallow trench 47 is formed, and the buried insulator 48 is buried in the shallow trench 47. The protrusion portion 39 of the main isolation conductor 33 and the protrusion portion 43 of the auxiliary isolation conductor 34 are formed by partially removing the tops of the main isolation conductor 33 and the auxiliary isolation conductor 34 by etching when forming the shallow trench 47. Next, a functional device such as the MISFET cell 70 is formed over the first wafer main surface 101 of the semiconductor wafer 100. Thereafter, the semiconductor wafer 100 is divided into a plurality of semiconductor devices 1A through a process of forming elements necessary for the semiconductor devices 1A. As a result, chips of the semiconductor devices 1A are obtained.

As described above, according to the semiconductor device 1A, the isolation conductor 17 of the first trench structure 13 has the auxiliary isolation conductor 34 in addition to the main isolation conductor 33. The auxiliary isolation conductor 34 is sandwiched between the buried region 8 and the main isolation conductor 33 in the lateral direction along the first main surface 3.

The buried region 8 covered with the auxiliary isolation conductor 34 is sandwiched between the p-type first impurity region 6 and the low-concentration n-type second impurity region 7, and it is thus easier for an electric field to concentrate on the buried region 8 than on the bottom 18 of the isolation trench 15. This is because an equipotential line is bent into an L-shape in a cross-section at a boundary between the isolation conductor 17 (having the same potential as the first impurity region 6), which is connected to the p-type first impurity region 6 and extends in the normal direction of the first main surface 3, and the n-type second impurity region 7 and the buried region 8, which are formed along the first main surface 3 and intersect the isolation conductor 17. The electric field tends to concentrate at a corner of the L-shaped portion of the equipotential line. Therefore, if electric field concentration occurs at the side wall 26 of the isolation trench 15 at a portion between the buried region 8 and the isolation conductor 17, a breakdown voltage of the semiconductor device 1A may decrease. Therefore, by providing the auxiliary isolation conductor 34 covering the buried region 8, it is possible to prevent at least the inner insulating film 30 from being destroyed even if the electric field is concentrated. As a result, the breakdown voltage in the lateral direction along the first main surface 3 of the semiconductor chip 2 may be improved.

Further, the auxiliary isolation conductor 34 is formed from the bottom 22 of the upper trench 24 to the top 23 thereof and covers the top 23. Since the top 23 of the isolation trench 15 has a corner at which the first main surface 3 and the side wall 26 intersect, the electric field tends to concentrate thereon. Since this top 23 is also covered with the auxiliary isolation conductor 34, a breakdown voltage of the isolation insulating film 16 at the top 23 of the isolation trench 15 may also be improved.

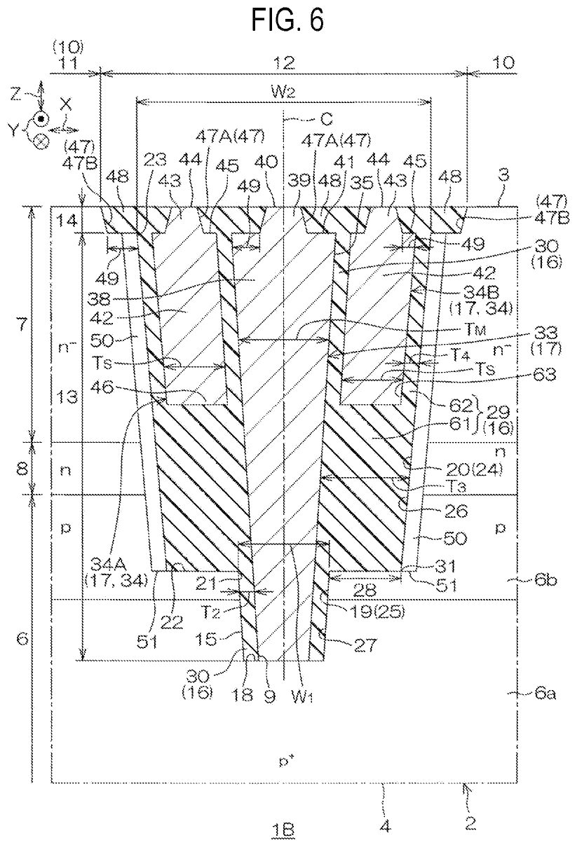

FIG. 6 is an enlarged cross-sectional view of a main part of a semiconductor device 1B according to a second embodiment of the present disclosure. In the following, structures corresponding to those described in FIG. 4 are denoted by the same reference numerals, and explanation thereof will not be repeated.

In the semiconductor device 1B, the outer insulating film 29 includes a thick film portion 61 and a thin film portion 62.

The thick film portion 61 is formed from the bottom 22 of the upper trench 24, across the boundary between the buried region 8 and the second impurity region 7, to a side of the second impurity region 7. As a result, the thick film portion 61 is sandwiched between the main isolation conductor 33 and both the second impurity region 7 and the buried region 8 in the lateral direction along the first main surface 3. The buried region 8 is covered with the thick film portion 61 of the outer insulating film 29 at the intermediate portion in the depth direction of the isolation trench 15. In this way, the thick film portion 61 of the outer insulating film 29 extends out from the inner insulating film 30 toward both the transistor region 11 and the opposite side thereof, and is supported from below by the step portion 28 of the isolation trench 15.

The thin film portion 62 is formed at the side wall 26 of the upper trench 24 from the thick film portion 61 to the first main surface 3. The auxiliary isolation conductor 34 is sandwiched between the second impurity region 7 and the main isolation conductor 33 via the thin film portion 62 in the lateral direction along the first main surface 3. That is, the auxiliary isolation conductor 34 is buried in a space 63 defined by the inner insulating film 30, the thick film portion 61, and the thin film portion 62. In the space 63, an entire lower surface of the auxiliary isolation conductor 34 is supported by the thick film portion 61. The lower end 46 of the auxiliary isolation conductor 34 may be located within the second impurity region 7.

A third thickness T₃ of the thick film portion 61 is two times or more, preferably two times or more and ten times or less, a fourth thickness T₄ of the thin film portion 62. The third thickness T₃ may be, for example, 100 Å or more and 1,000 Å or less. Further, the fourth thickness T₄ may be, for example, 100 Å or more and 500 Å or less.

As described above, according to this semiconductor device 1B, the thick film portion 61 that covers the buried region 8 is provided. As a result, a breakdown voltage of the isolation insulating film 16 in the buried region 8 may be improved. Therefore, even if an electric field concentration occurs, it is possible to prevent the isolation insulating film 16 (the outer insulating film 29) from being destroyed. As a result, similarly to the semiconductor device 1A, a breakdown voltage in the lateral direction along the first main surface 3 of the semiconductor chip 2 may be improved.

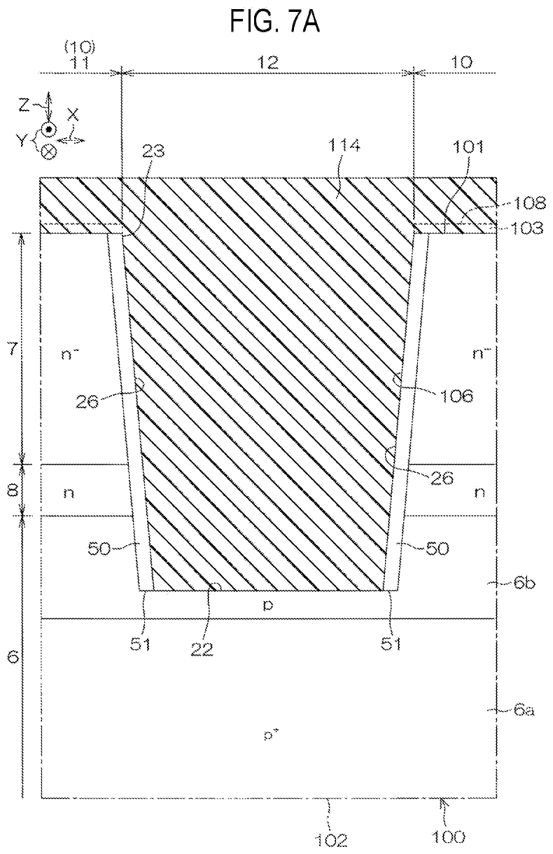

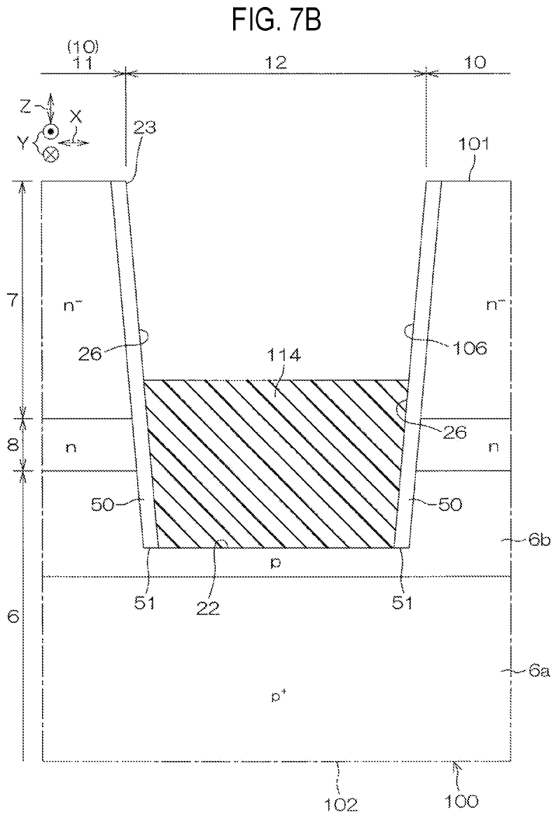

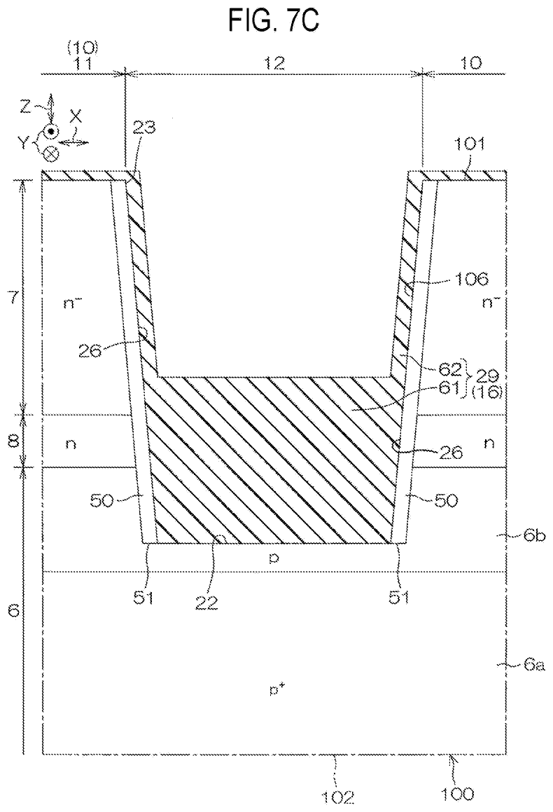

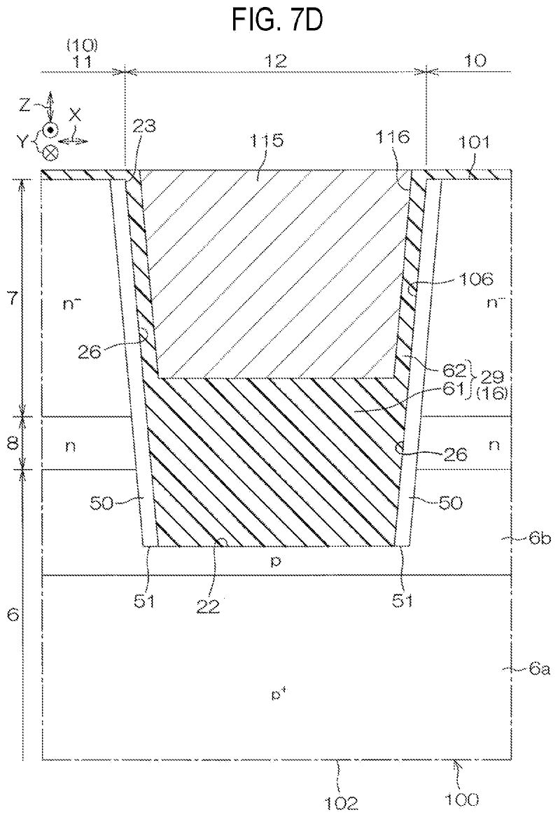

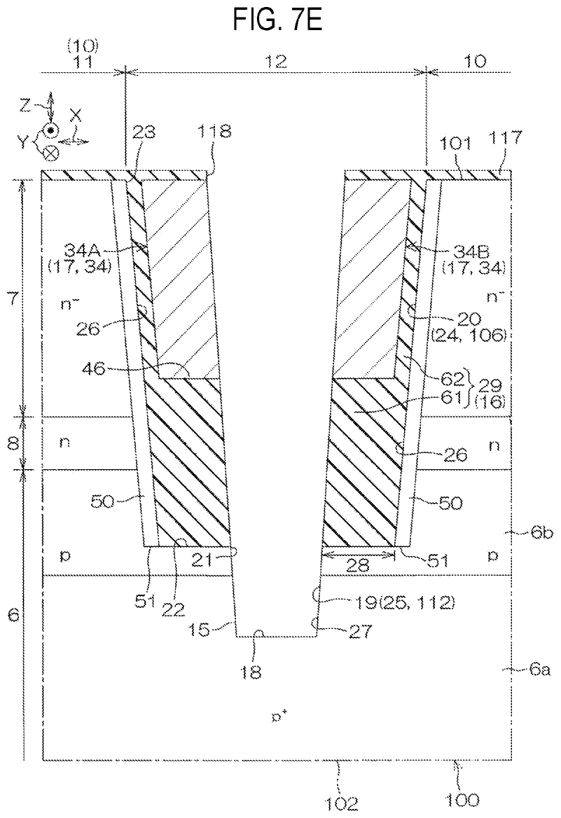

FIGS. 7A to 7E are views corresponding to FIG. 6, and show parts of a process of manufacturing the semiconductor device 1B according to the second embodiment of the present disclosure. In the following, structures corresponding to those described in FIGS. 5A to 5L are denoted by the same reference numerals, and explanation thereof will be omitted.

In order to manufacture the semiconductor device 1B, after going through the steps of FIGS. 5A to 5D, as shown in FIG. 7A, a first insulating material 114, which becomes a base of the thick film portion 61 of the outer insulating film 29, is deposited on the first wafer main surface 101 through the mask 103. The first insulating material 114 may be silicon oxide (SiO₂) or tetraethyl orthosilicate (TEOS). The deposition of the first insulating material 114 continues until the first trench 106 is filled. The first insulating material 114 may be formed, for example, by thermally oxidizing the inner wall of the first trench 106 to form a thermal oxide film at a surface layer of the inner wall and then depositing TEOS by a CVD method to backfill the first trench 106 with SiO₂. Further, in FIG. 7A, a boundary 108 between the mask 103 and the first insulating material 114 is shown by a broken line because the mask 103 and the first insulating material 114, which are made of SiO₂, may be integrated such that the boundary is not visually recognizable.

Next, referring to FIG. 7B, unnecessary portions of the deposited first insulating material 114 are removed. This step includes a step of removing the first insulating material 114 by a grinding method until an upper surface of the first insulating material 114 is at a depth position along a thickness direction of the second impurity region 7. The grinding method may be a CMP (Chemical Mechanical Polishing) method.

Next, referring to FIG. 7C, the thin film portion 62 of the outer insulating film 29 is formed at the side wall 26 of the first trench 106. The thin film portion 62 may be formed, for example, by thermal oxidation of the side wall 26 of the first trench 106. As a result, the outer insulating film 29 in which the thin film portion 62 and the thick film portion 61 are integrated is obtained.

Next, referring to FIG. 7D, a polysilicon material 115, which becomes the base of the auxiliary isolation conductor 34, is deposited on the first wafer main surface 101. In this embodiment, the polysilicon material 115 includes doped polysilicon added with p-type (first conductivity type) impurities. The deposition of the polysilicon material 115 continues until a space 116 defined by the thick film portion 61 and the thin film portion 62 is filled. The polysilicon material 115 may be deposited by a CVD method. Thereafter, unnecessary portions of the deposited polysilicon material 115 are removed. This step includes a step of removing the polysilicon material 115 by a grinding method until the outer insulating film 29 is exposed. The grinding method may be a CMP (Chemical Mechanical Polishing) method.

Next, referring to FIG. 7E, the remaining portion of the outer insulating film 29 (the thin film portion 62) on the first wafer main surface 101 is removed, and another mask 117 is newly formed over the entire first wafer main surface 101. The mask 117 may be a hard mask made of, for example, silicon oxide (SiO₂). The mask 117 is formed by, for example, a thermal oxidation method or a CVD method.

Next, an opening 118 having a shape corresponding to the lower trench 25 (the first portion 19) of the isolation trench 15 is formed at the mask 117, and then the polysilicon material 115 is selectively etched through the opening 118 of the mask 117. The etching of the polysilicon material 115 continues until the thick film portion 61 of the outer insulating film 29 is exposed. As a result, the polysilicon material 115 is separated, and the pair of auxiliary isolation conductors 34 are formed. Next, after the thick film portion 61 of the outer insulating film 29 exposed between the pair of auxiliary isolation conductors 34 is removed, the bottom 22 of the first trench 106 is further etched. As a result, the second trench 112 having a narrower width than the first trench 106 is formed, and the isolation trench 15 having a two-stage trench structure is formed.

Thereafter, the same steps as in FIGS. 5I to 5L are performed to obtain the semiconductor device 1B.

Although the embodiments of the present disclosure have been described, the present disclosure may be implemented in other forms.

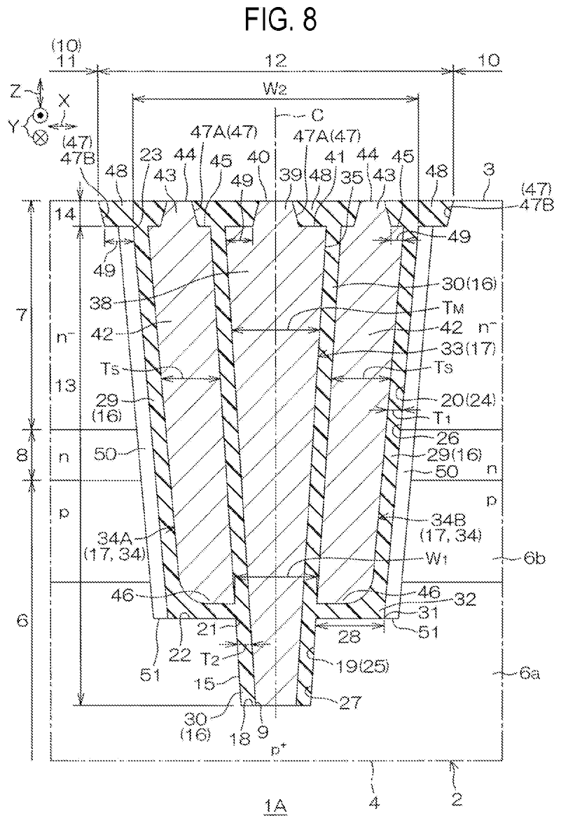

For example, referring to FIG. 8, the upper trench 24 may reach the high-concentration region 6a of the first impurity region 6 from the first main surface 3. As a result, the bottom 22 of the second portion 20 of the isolation trench 15 may be located in the high-concentration region 6a, and the lower end 46 of the pair of auxiliary isolation conductors 34 may be located within the high-concentration region 6a (in this embodiment, a p-type semiconductor substrate).

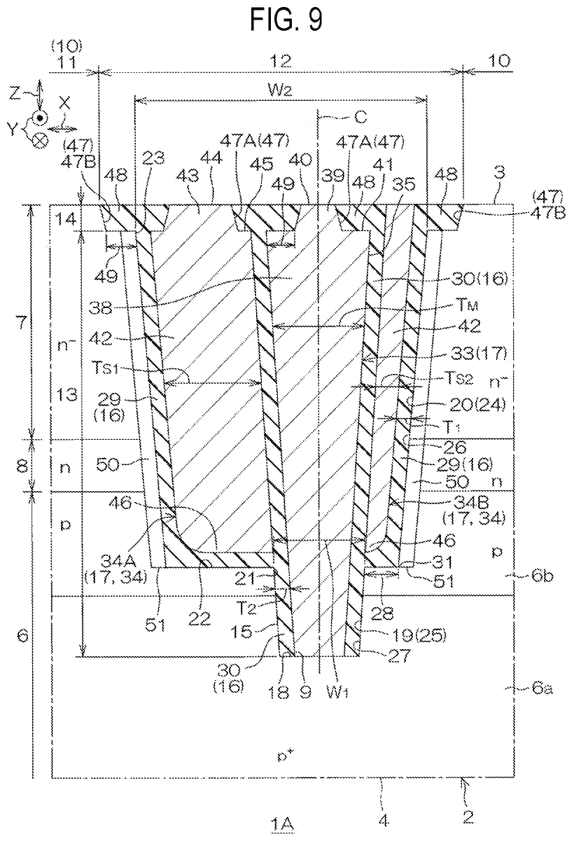

For example, referring to FIG. 9, the pair of auxiliary isolation conductors 34A and 34B may be formed in non-line symmetry to the center line C. In FIG. 9, it is assumed that a HV-MISFET cell is mounted at the device region 10 on a left side of the diagram and a LV-MISFET cell is mounted at the device region 10 on a right side of the diagram. In this case, by setting a thickness T_{S1} of the auxiliary isolation conductor 34A on the left side of the diagram to be thicker than a thickness T_{S2} of the auxiliary isolation conductor 34B on the right side of the diagram, the auxiliary isolation conductor 34 may be provided with an appropriate thickness depending on a breakdown voltage of each device region 10.

In order to form the pair of auxiliary isolation conductors 34A and 34B having different thicknesses, in the step of FIG. 5H, the second trench 112 may be formed such that a center of the second trench 112 in a width direction is located at a position biased towards either one of the device regions 10 on one side or the other side, with respect to a center of the bottom 22 of the first trench 106 in the width direction.

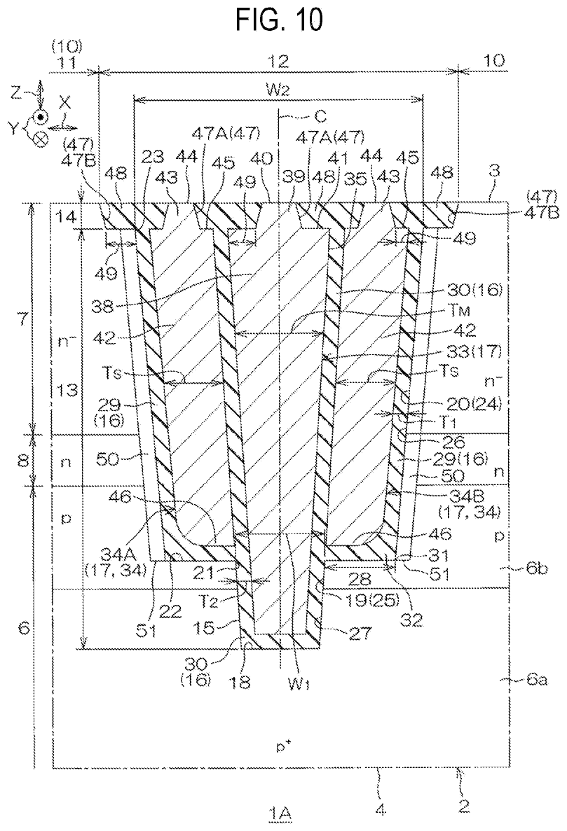

Regarding a modification of the isolation insulating film 16, for example, referring to FIG. 10, the contact opening 9 may not be formed at the inner insulating film 30. In this case, the main isolation conductor 33 is insulated from the first impurity region 6 (in this embodiment, the high-concentration region 6a) by the inner insulating film 30.

As an example, in the above-described embodiments, the buried region 8 has been shown as an example of an electric field concentration portion in the semiconductor chip 2, but a target for improving the breakdown voltage by covering the auxiliary isolation conductor 34 is not limited to the buried region 8. For example, the target may be the top 23 of the second portion 20 of the isolation trench 15.

As an example, although the element isolation portion 12 has been described as one that annularly surrounds one transistor region 11 and isolates it from another device region 10, it may also define a boundary between two adjacent transistor regions 11.

As an example, a configuration may be adopted in which the conductivity type of each semiconductor portion of the semiconductor devices 1A and 1B is reversed. For example, in the semiconductor devices 1A and 1B, the p-type (first conductivity type) portion may be n-type, and the n-type (second conductivity type) portion may be p-type.

As described above, the embodiments of the present disclosure are illustrative in all respects and should not be construed as limiting, and are intended to include changes in all respects.

The features described below may be extracted from the description of the present disclosure and the drawings.

### [Supplementary Note 1-1]

A semiconductor device (1A, 1B) including:
a semiconductor chip (2) including a first main surface (3) and a second main surface (4) opposite to the first main surface (3); and
an element isolation portion (12) formed at the first main surface (3) of the semiconductor chip (2) and partitioning a device region (10, 11),
wherein the element isolation portion (12) includes:
   a first isolation trench (15) formed at the first main surface (3) of the semiconductor chip (2);
   an isolation insulating film (16) formed at an inner wall of the first isolation trench (15); and
   an isolation conductor (17) buried in the first isolation trench (15) via the isolation insulating film (16), and
wherein the isolation conductor (17) includes:
   a main isolation conductor (33) formed at a central portion of the first isolation trench (15); and
   at least one auxiliary isolation conductor (34) formed at a side of the main isolation conductor (33) with an inner insulating film (30), which is a portion of the isolation insulating film (16), interposed between the main isolation conductor (33) and the at least one auxiliary isolation conductor (34).

According to this configuration, the isolation conductor (17) includes the auxiliary isolation conductor (34) in addition to the main isolation conductor (33). Accordingly, even if an electric field is concentrated in the lateral direction along the first main surface (3), it is possible to prevent at least the inner insulating film (30) from being destroyed. As a result, it is possible to improve a breakdown voltage in the lateral direction along the first main surface (3) of the semiconductor chip (2).

### [Supplementary Note 1-2]

The semiconductor device (1A, 1B) of Supplementary Note 1-1, wherein the first isolation trench (15) includes:
a first portion (19) having a first width (W₁) formed at a bottom (18) of the first isolation trench (15); and
a second portion (20) that is formed at the first main surface (3) with respect to the first portion, is formed to extend from the first portion (19) toward an outside of the first isolation trench (15), and has a second width (W₂) wider than the first width (W₁), and
wherein the main isolation conductor (33) and the at least one auxiliary isolation conductor (34) are adjacent to each other in the second portion (20) of the first isolation trench (15).

### [Supplementary Note 1-3]

The semiconductor device (1A, 1B) of Supplementary Note 1-1, wherein the first isolation trench (15) includes a two-stage trench structure including an upper trench (24) formed from the first main surface (3) toward the second main surface (4), and a lower trench (25) that is formed by selectively digging a portion of the semiconductor chip (2) from a bottom (22) of the upper trench (24) and has a width (W₁) narrower than the upper trench (24), and
wherein the main isolation conductor (33) and the at least one auxiliary isolation conductor (34) are adjacent to each other in the upper trench (24) of the first isolation trench (15).

### [Supplementary Note 1-4]

The semiconductor device (1A, 1B) of any one of Supplementary Notes 1-1 to 1-3, wherein the main isolation conductor (33) has a bottom at a deeper position than the at least one auxiliary isolation conductor (34) in a thickness direction of the semiconductor chip (2).

### [Supplementary Note 1-5]

The semiconductor device (1A, 1B) of any one of Supplementary Notes 1-1 to 1-4, wherein the at least one auxiliary isolation conductor (34) is fixed at a third potential (V₃) between a first potential (V₁) of the main isolation conductor (33) and a second potential (V₂) of the device region (10, 11).

### [Supplementary Note 1-6]

The semiconductor device (1A, 1B) of any one of Supplementary Notes 1-1 to 1-5, wherein the semiconductor chip (2) includes:
a first impurity region (6) of a first conductivity type formed at the second main surface (4);
a second impurity region (7) of a second conductivity type formed at the first main surface (3); and
a buried region (8) of the second conductivity type buried between the first impurity region (6) and the second impurity region (7),
wherein the first isolation trench (15) penetrates from the first main surface (3) through the second impurity region (7) and the buried region (8) and has a bottom (18) in the first impurity region (6), and
wherein the at least one auxiliary isolation conductor (34) is sandwiched between the main isolation conductor (33) and both the second impurity region (7) and the buried region (8) in a lateral direction along the first main surface (3).

### [Supplementary Note 1-7]

The semiconductor device (1A, 1B) of Supplementary Note 1-6, wherein the semiconductor chip (2) further includes a sinker region (50) of the second conductivity type that is formed along a side wall (26) of the first isolation trench (15) in the second impurity region (7) and has a concentration higher than a concentration of the second impurity region (7).

### [Supplementary Note 1-8]

The semiconductor device (1A, 1B) of Supplementary Note 1-6 or 1-7, wherein the first impurity region (6) includes:
a substrate (6a) of the first conductivity type; and
an epitaxial layer (6b) of the first conductivity type having a concentration lower than a concentration of the substrate (6a),
wherein a lower end (46) of the at least one auxiliary isolation conductor (34) is disposed within the substrate (6a).

### [Supplementary Note 1-9]

The semiconductor device (1A, 1B) of any one of Supplementary Notes 1-6 to 1-8, wherein the inner insulating film (30) includes an opening (9) at a bottom (18) of the first isolation trench (15), and
wherein the main isolation conductor (33) is electrically connected to the first impurity region (6) via the opening (9).

### [Supplementary Note 1-10]

The semiconductor device (1A) of Supplementary Note 1-3, wherein the semiconductor chip (2) includes:
a first impurity region (6) of a first conductivity type formed at the second main surface (4);
a second impurity region (7) of a second conductivity type formed at the first main surface (3); and
a buried region (8) of the second conductivity type buried between the first impurity region (6) and the second impurity region (7),
wherein the upper trench (24) penetrates from the first main surface (3) through the second impurity region (7) and the buried region (8) and has a bottom (22) in the first impurity region (6),
wherein the isolation insulating film (16) includes an outer insulating film (29) formed to have a uniform thickness from the bottom (22) of the upper trench (24), across a boundary between the buried region (8) and the second impurity region (7), toward the second impurity region (7), and
wherein the at least one auxiliary isolation conductor (34) is sandwiched between the main isolation conductor (33) and both the second impurity region (7) and the buried region (8) via the outer insulating film (29) in a lateral direction along the first main surface (3).

### [Supplementary Note 1-11]

The semiconductor device (1B) of Supplementary Note 1-3, wherein the semiconductor chip (2) includes:
a first impurity region (6) of a first conductivity type formed at the second main surface (4);
a second impurity region (7) of a second conductivity type formed at the first main surface (3); and
a buried region (8) of the second conductivity type buried between the first impurity region (6) and the second impurity region (7),
wherein the upper trench (24) penetrates from the first main surface (3) through the second impurity region (7) and the buried region (8) and has a bottom (22) in the first impurity region (6),
wherein the isolation insulating film (16) includes an outer insulating film (29) having a thick film portion (61) that is formed from the bottom (22) of the upper trench (24), across a boundary between the buried region (8) and the second impurity region (7), to a side of the second impurity region (7), and a thin film portion (62) that is formed from the thick film portion (61) to the first main surface (3) and is thinner than the thick film portion (61), and
wherein the at least one auxiliary isolation conductor (34) is sandwiched between the second impurity region (7) and the main isolation conductor (33) via the thin film portion (62) in a lateral direction along the first main surface (3).

### [Supplementary Note 1-12]

The semiconductor device (1A, 1B) of any one of Supplementary Notes 1-1 to 1-11, wherein the at least one auxiliary isolation conductor (34) includes a pair of auxiliary isolation conductors (34A, 34B),
wherein the isolation conductor (17) includes the pair of auxiliary isolation conductors (34A, 34B) that are separated from each other in a cross-sectional view, and
wherein the pair of auxiliary isolation conductors (34A, 34B) are formed in line symmetry to a center line (C) extending from a center at a width direction of the bottom (18) of the first isolation trench (15), so as to have a same thickness (T_{S}).

### [Supplementary Note 1-13]

The semiconductor device (1A, 1B) of any one of Supplementary Notes 1-1 to 1-11, wherein the at least one auxiliary isolation conductor (34) includes a pair of auxiliary isolation conductors (34A, 34B),
wherein the isolation conductor (17) includes the pair of auxiliary isolation conductors (34A, 34B) that are separated from each other in a cross-sectional view, and
wherein the pair of auxiliary isolation conductors (34A, 34B) are formed in non-line symmetry to a center line (C) extending from a center at a width direction of the bottom (18) of the first isolation trench (15), so as to have different thicknesses (T_{S1}, T_{S2}).

### [Supplementary Note 1-14]

The semiconductor device (1A, 1B) of any one of Supplementary Notes 1-1 to 1-13 further including:
a second isolation trench (47) that is formed at a surface layer of the first main surface (3) of the semiconductor chip (2) to be continuous with the first isolation trench (15) and is shallower than the first isolation trench (15); and
a buried insulator (48) buried in the second isolation trench (47).

### [Supplementary Note 1-15]

The semiconductor device (1A, 1B) of Supplementary Note 1-14, wherein the second isolation trench (47) is formed across a boundary between the main isolation conductor (33) and the at least one auxiliary isolation conductor (34) in a lateral direction along the first main surface (3), and
wherein the buried insulator (48) includes an insulator (48) formed integrally with the inner insulating film (30).

### [Supplementary Note 1-16]

A method of manufacturing a semiconductor device (1A, 1B), including:
forming an annular first trench (106) to partition a device region (10, 11) at a first main surface (101) of a semiconductor wafer (100) including the first main surface (101) and a second main surface (102) opposite to the first main surface (101);
forming an outer insulating film (29) at an inner wall of the first trench (106);
burying a first conductor (107) in the first trench (106) via the outer insulating film (29);
forming a second trench (112) having a narrower width than the first trench (106) and forming an auxiliary isolation conductor (34) formed of the first conductor (107) remaining on a side wall of the second trench (112), by selectively etching the first conductor (107) and a portion of the semiconductor wafer (100) below the first conductor (107);
forming an inner insulating film (30) at a portion of the auxiliary isolation conductor (34) of an inner wall of the second trench (112) and a portion of the semiconductor wafer (100); and
forming a main isolation conductor (33) by burying a conductive material (113) in the second trench (112).

According to this method, it is possible to provide a semiconductor device (1A, 1B) that may improve a breakdown voltage in the lateral direction along the first main surface (3) of the semiconductor chip (2).

### [Supplementary Note 1-17]

The method of Supplementary Note 1-16, wherein the semiconductor wafer (100) includes:
a first impurity region (6) of a first conductivity type formed at the second main surface (102);
a second impurity region (7) of a second conductivity type formed at the first main surface (101); and
a buried region (8) of the second conductivity type buried between the first impurity region (6) and the second impurity region (7),
wherein the first trench (106) is formed from the first main surface (101) through the second impurity region (7) and the buried region (8) so that a bottom of the first trench (106) reaches the first impurity region (6).

### [Supplementary Note 1-18]

The method of Supplementary Note 1-16 or 1-17, wherein the forming the outer insulating film (29) includes forming an insulating film (29) with a uniform thickness at the inner wall of the first trench (106) by thermal oxidation.

### [Supplementary Note 1-19]

The method of Supplementary Note 1-16 or 1-17, wherein the forming the outer insulating film (29) includes burying a thick insulating film (61, 114) along a depth direction of the first trench (106) and forming a thin insulating film (62) having a uniform thickness, which is thinner than the thick insulating film (61, 114), at the inner wall of the first trench (106) above the thick insulating film (114) by thermal oxidation.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor chip including a first main surface and a second main surface opposite to the first main surface; and
an element isolation portion formed at the first main surface of the semiconductor chip and partitioning a device region,
wherein the element isolation portion includes:
a first isolation trench formed at the first main surface of the semiconductor chip;
an isolation insulating film formed at an inner wall of the first isolation trench; and
an isolation conductor buried in the first isolation trench via the isolation insulating film, and
wherein the isolation conductor includes:
a main isolation conductor formed at a central portion of the first isolation trench; and
at least one auxiliary isolation conductor formed at a side of the main isolation conductor with an inner insulating film, which is a portion of the isolation insulating film, interposed between the main isolation conductor and the at least one auxiliary isolation conductor.

2. The semiconductor device of claim 1, wherein the first isolation trench includes:
a first portion having a first width formed at a bottom of the first isolation trench; and
a second portion that is formed at the first main surface with respect to the first portion, is formed to extend from the first portion toward an outside of the first isolation trench, and has a second width wider than the first width, and
wherein the main isolation conductor and the at least one auxiliary isolation conductor are adjacent to each other in the second portion of the first isolation trench.

3. The semiconductor device of claim 1, wherein the first isolation trench includes a two-stage trench structure including an upper trench formed from the first main surface toward the second main surface, and a lower trench that is formed by selectively digging a portion of the semiconductor chip from a bottom of the upper trench and has a width narrower than the upper trench, and
wherein the main isolation conductor and the at least one auxiliary isolation conductor are adjacent to each other in the upper trench of the first isolation trench.

4. The semiconductor device of claim 1, wherein the main isolation conductor has a bottom at a deeper position than the at least one auxiliary isolation conductor in a thickness direction of the semiconductor chip.

5. The semiconductor device of claim 1, wherein the at least one auxiliary isolation conductor is fixed at a third potential between a first potential of the main isolation conductor and a second potential of the device region.

6. The semiconductor device of claim 1, wherein the semiconductor chip includes:
a first impurity region of a first conductivity type formed at the second main surface;
a second impurity region of a second conductivity type formed at the first main surface; and
a buried region of the second conductivity type buried between the first impurity region and the second impurity region,
wherein the first isolation trench penetrates from the first main surface through the second impurity region and the buried region and has a bottom in the first impurity region, and
wherein the at least one auxiliary isolation conductor is sandwiched between the main isolation conductor and both the second impurity region and the buried region in a lateral direction along the first main surface.

7. The semiconductor device of claim 6, wherein the semiconductor chip further includes a sinker region of the second conductivity type that is formed along a side wall of the first isolation trench in the second impurity region and has a concentration higher than a concentration of the second impurity region.

8. The semiconductor device of claim 6, wherein the first impurity region includes:
a substrate of the first conductivity type; and
an epitaxial layer of the first conductivity type having a concentration lower than a concentration of the substrate,
wherein a lower end of the at least one auxiliary isolation conductor is disposed within the substrate.

9. The semiconductor device of claim 6, wherein the inner insulating film includes an opening at a bottom of the first isolation trench, and
wherein the main isolation conductor is electrically connected to the first impurity region via the opening.

10. The semiconductor device of claim 3, wherein the semiconductor chip includes:
a first impurity region of a first conductivity type formed at the second main surface;
a second impurity region of a second conductivity type formed at the first main surface; and
a buried region of the second conductivity type buried between the first impurity region and the second impurity region,
wherein the upper trench penetrates from the first main surface through the second impurity region and the buried region and has a bottom in the first impurity region,
wherein the isolation insulating film includes an outer insulating film formed to have a uniform thickness from the bottom of the upper trench, across a boundary between the buried region and the second impurity region, toward the second impurity region, and
wherein the at least one auxiliary isolation conductor is sandwiched between the main isolation conductor and both the second impurity region and the buried region via the outer insulating film in a lateral direction along the first main surface.

11. The semiconductor device of claim 3, wherein the semiconductor chip includes:
a first impurity region of a first conductivity type formed at the second main surface;
a second impurity region of a second conductivity type formed at the first main surface; and
a buried region of the second conductivity type buried between the first impurity region and the second impurity region,
wherein the upper trench penetrates from the first main surface through the second impurity region and the buried region and has a bottom in the first impurity region,
wherein the isolation insulating film includes an outer insulating film including a thick film portion that is formed from the bottom of the upper trench, across a boundary between the buried region and the second impurity region, to a side of the second impurity region, and a thin film portion that is formed from the thick film portion to the first main surface and is thinner than the thick film portion, and
wherein the at least one auxiliary isolation conductor is sandwiched between the second impurity region and the main isolation conductor via the thin film portion in a lateral direction along the first main surface.

12. The semiconductor device of claim 1, wherein the at least one auxiliary isolation conductor includes a pair of auxiliary isolation conductors,
wherein the isolation conductor includes the pair of auxiliary isolation conductors that are separated from each other in a cross-sectional view, and
wherein the pair of auxiliary isolation conductors are formed in line symmetry to a center line extending from a center at a width direction of the bottom of the first isolation trench, so as to have a same thickness.

13. The semiconductor device of claim 1, wherein the at least one auxiliary isolation conductor includes a pair of auxiliary isolation conductors,
wherein the isolation conductor includes the pair of auxiliary isolation conductors that are separated from each other in a cross-sectional view, and
wherein the pair of auxiliary isolation conductors are formed in non-line symmetry to a center line extending from a center at a width direction of the bottom of the first isolation trench, so as to have different thicknesses.

14. The semiconductor device of claim 1, further comprising:
a second isolation trench that is formed at a surface layer of the first main surface of the semiconductor chip to be continuous with the first isolation trench and is shallower than the first isolation trench; and
a buried insulator buried in the second isolation trench.

15. The semiconductor device of claim 14, wherein the second isolation trench is formed across a boundary between the main isolation conductor and the at least one auxiliary isolation conductor in a lateral direction along the first main surface, and
wherein the buried insulator includes an insulator formed integrally with the inner insulating film.

16. A method of manufacturing a semiconductor device, comprising:
forming an annular first trench to partition a device region at a first main surface of a semiconductor wafer including the first main surface and a second main surface opposite to the first main surface;
forming an outer insulating film at an inner wall of the first trench;
burying a first conductor in the first trench via the outer insulating film;
forming a second trench having a narrower width than the first trench and forming an auxiliary isolation conductor formed of the first conductor remaining on a side wall of the second trench, by selectively etching the first conductor and a portion of the semiconductor wafer below the first conductor;
forming an inner insulating film at a portion of the auxiliary isolation conductor of an inner wall of the second trench and a portion of the semiconductor wafer; and
forming a main isolation conductor by burying a conductive material in the second trench.

17. The method of claim 16, wherein the semiconductor wafer includes:
a first impurity region of a first conductivity type formed at the second main surface;
a second impurity region of a second conductivity type formed at the first main surface; and
a buried region of the second conductivity type buried between the first impurity region and the second impurity region,
wherein the first trench is formed from the first main surface through the second impurity region and the buried region so that a bottom of the first trench reaches the first impurity region.

18. The method of claim 16, wherein the forming the outer insulating film includes forming an insulating film with a uniform thickness at the inner wall of the first trench by thermal oxidation.

19. The method of claim 16, wherein the forming the outer insulating film includes burying a thick insulating film along a depth direction of the first trench and forming a thin insulating film having a uniform thickness, which is thinner than the thick insulating film, at the inner wall of the first trench above the thick insulating film by thermal oxidation.
